(19) United States
(12) Patent Application Publication
(10) Pub. No.: US 2026/0371984 A1
(43) Pub. Date: Nov. 19, 2026

(54) SUBSTRATE CLEANING APPARATUS AND SUBSTRATE CLEANING METHOD USING SAME

(71) Applicant: KSEMI CO., LTD., Cheonan-si, Chungcheongnam-do (KR)

(72) Inventor: Kyo Woog KOO, Cheonan-si (KR)

(73) Assignee: KSEMI CO., LTD., Cheonan-si, Chungcheongnam-do (KR)

(21) Appl. No.: 19/515,689

(22) PCT Filed: Jul. 26, 2024
(86) PCT No.: PCT/KR2024/010960

§ 371 Date: Mar. 2, 2026

(30) Foreign Application Priority Data
Sep. 14, 2023 (KR) 10-2023-0116816

(51) Int. Cl. H10P 72/00; B08B 3/04; B08B 3/08; B08B 3/10; H10P 70/00; H10P 72/76

(52) U.S. Cl. CPC H10P 72/0414; B08B 3/041; B08B 3/08; B08B 3/10; H10P 70/20; H10P 72/7618

(57) ABSTRACT

A substrate cleaning apparatus including a substrate rotation module configured to support and fix a substrate for cleaning and to rotate the substrate about a virtual central axis line; a chemical liquid supply module having an upper chemical liquid supply unit configured to supply a chemical liquid to an upper surface of the substrate and a lower chemical liquid supply unit configured to supply a chemical liquid to a lower surface of the substrate; and a bowl module disposed outside the substrate rotation module and configured to discharge the chemical liquid scattered from the substrate by rotation and a substrate cleaning method using the same. A chemical-liquid filling space is formed between an upper surface of a spin chuck and a lower surface of the substrate, and cleaning of the substrate is performed while the lower surface is immersed in the chemical liquid filled in the chemical-liquid filling space.

### TECHNICAL FIELD

The present invention relates to a substrate cleaning apparatus and a substrate cleaning method using the same, and more particularly, to a substrate cleaning apparatus in which a cleaning process is uniformly performed on an upper surface and a lower surface of a substrate, and a substrate cleaning method using the same.

### BACKGROUND ART

In general, in a process of manufacturing a substrate, a cleaning process for removing foreign substances from a surface of the substrate is one of the essential processes for increasing yield of the substrate. Specifically, after processes such as deposition of an insulating film and a metal material, etching, and application of a photoresist are performed, various impurities may remain on the surface of the substrate. Since such impurities are an important factor determining performance and yield of the substrate, a substrate cleaning process is very important.

Such cleaning of a substrate is performed by spraying a chemical liquid to a center of the substrate from an upper side and a lower side of the substrate while the substrate is rotating, thereby cleaning the substrate. That is, the chemical liquid sprayed to the substrate is moved from a central portion to an edge portion of the substrate by centrifugal force of the rotating substrate, and the upper surface and the lower surface of the substrate are cleaned overall.

However, since a lower chemical liquid supply unit for spraying a chemical liquid to the lower surface of the substrate generally sprays a chemical liquid to the center of the substrate in a fixed state, cleaning of the lower surface of the substrate may not be properly performed depending on a rotational speed condition of the substrate or a flow rate condition of the chemical liquid. In other words, when the chemical liquid sprayed to the center of the substrate is not continuously supplied to the edge portion of the substrate and drops in the middle, substrate cleaning is not properly performed. Due to such a problem, a substrate cleaning operation is sometimes performed with the substrate turned over.

In addition, since a substrate cleaning apparatus cleans a substrate with, for example, a high-temperature chemical liquid of 120 °C or higher, an infrared lamp may be used to maintain a temperature of the substrate at a predetermined temperature in advance for effective substrate cleaning. However, in a conventional substrate cleaning apparatus, since an infrared lamp is installed on an upper side of a substrate, interference may occur during movement of an upper chemical liquid supply unit, and an overall apparatus structure becomes complicated.

Accordingly, various research and development have been conducted for a substrate cleaning apparatus in which cleaning is uniformly performed on an upper surface and a lower surface of a substrate.

### DETAILED DESCRIPTION OF THE INVENTION

### Technical Problem

A technical problem of the present invention for solving the above problems is to provide a substrate cleaning apparatus in which cleaning is uniformly performed on an upper surface and a lower surface of a substrate, and a substrate cleaning method using the same.

### Technical Solution

In order to accomplish the above technical problem, one embodiment of the present invention provides a substrate cleaning apparatus including: a substrate rotation module supporting and fixing a substrate for cleaning and rotating the substrate about a virtual central axis line; a chemical liquid supply module having an upper chemical liquid supply unit supplying a chemical liquid to an upper surface of the substrate and a lower chemical liquid supply unit supplying a chemical liquid to a lower surface of the substrate; and a bowl module disposed outside the substrate rotation module and discharging the chemical liquid scattered from the substrate by rotation, wherein a chemical-liquid filling space is formed between an upper surface of a spin chuck provided in the substrate rotation module and a lower surface of the substrate fixed to the substrate rotation module, and cleaning of the substrate is performed while the lower surface of the substrate is immersed in the chemical liquid filled in the chemical-liquid filling space.

In one embodiment of the present invention, a chemical liquid discharge blade provided at a periphery of the spin chuck is inserted into a blade insertion groove of a first bowl provided in the bowl module, and, in a state in which the chemical liquid discharge blade is inserted into the blade insertion groove, an upper end of a chemical liquid receiving ledge forming the blade insertion groove may be disposed higher than the lower surface of the substrate and lower than the upper surface of the substrate.

In one embodiment of the present invention, the blade insertion groove forms a second separation space with the chemical liquid discharge blade, and the blade insertion groove may be formed to be inclined such that the blade insertion groove becomes closer to the central axis line from an upper side to a lower side.

In one embodiment of the present invention, a plurality of lamps are provided on a lower surface of the spin chuck at predetermined intervals in an outward direction with respect to the central axis line, and thermal energy generated from the lamps is transmitted to the substrate through the chemical liquid received in the chemical-liquid filling space so that the substrate maintains a predetermined temperature, and the plurality of lamps may be configured to be individually controllable.

In one embodiment of the present invention, the substrate rotation module may include: the spin chuck; a plurality of substrate fixing units disposed at predetermined intervals along an outer circumference of the spin chuck and supporting and fixing a periphery of the substrate in a state in which the substrate is spaced apart from an upper surface of the spin chuck by a predetermined distance; a rotational driving unit rotating the spin chuck; a power support unit having a hollow portion into which the rotational driving unit is inserted and fixed and supporting the rotational driving unit; and a bellows having one end coupled to the power support unit and the other end coupled to a seating surface formed in the bowl module.

In one embodiment of the present invention, each of the substrate fixing units may include: a chuck pin supporting an upper edge portion of the substrate; a chuck pin pressing part inserted into a chuck fixing groove formed in the spin chuck and supporting a lower edge portion of the substrate together with the chuck pin; a chuck pin shaft inserted through the chuck pin pressing part and having an upper end coupled to the chuck pin; a spring inserted through the chuck pin shaft, with one end supported by a chuck pin support portion in which the chuck fixing groove is formed and the other end supported by a pressing support surface provided at a lower end portion of the chuck pin shaft; and a height adjustment ring pressing the pressing support surface and guiding upward and downward movement of the chuck pin shaft.

In one embodiment of the present invention, an extension guide coupled to the chuck pin support portion may be disposed outside the bellows, and a lower end of the extension guide may be disposed lower than an upper end of the bellows.

In one embodiment of the present invention, the lower chemical liquid supply unit may include: a lower chemical liquid nozzle spraying a chemical liquid toward the lower surface of the substrate; and a central drain port discharging the chemical liquid that has flowed into a first separation space between the lower chemical liquid nozzle and the spin chuck to the outside.

In one embodiment of the present invention, the bowl module may include: the first bowl; a second bowl spaced apart above the first bowl and forming a first discharge space together with the first bowl; a third bowl spaced apart above the second bowl and forming a second discharge space together with the second bowl; and a bowl casing spaced apart above the third bowl, forming a third discharge space together with the third bowl, and protecting the first to the third bowls.

In one embodiment of the present invention, a seating surface to which a lower portion of the bellows provided in the substrate rotation module is coupled is formed in the first bowl, and a bottom drain port for discharging the chemical liquid that has flowed through a second separation space between the chemical liquid discharge blade provided at the periphery of the spin chuck and the blade insertion groove is provided in the seating surface, and the chemical liquid discharged through the first discharge space may be discharged through a side drain port penetrating the first bowl.

One embodiment of the present invention provides a substrate cleaning method including: (a) loading a substrate onto a substrate rotation module at an upper side of an outermost bowl; (b) positioning the substrate rotation module between a first bowl and a second bowl; (c) spraying a chemical liquid toward an upper surface and a lower surface of the substrate positioned between the first bowl and the second bowl, by an upper chemical liquid supply unit and a lower chemical liquid supply unit; (d) performing rinsing and drying of the substrate in the outermost bowl, by the substrate rotation module; (e) stopping rotation of the substrate, and positioning the substrate rotation module at an upper side of the outermost bowl; and (f) unloading the substrate, by a robot, wherein, in step (b), the substrate is cleaned while the lower surface of the substrate is immersed in the chemical liquid received in a chemical-liquid filling space.

In one embodiment of the present invention, in step (c), a plurality of lamps are provided on a lower surface of a spin chuck provided in the substrate rotation module at predetermined intervals in an outward direction with respect to a central axis line, and the lamps may transmit thermal energy to the substrate through the chemical liquid received in the chemical-liquid filling space to maintain the substrate at a predetermined temperature.

In one embodiment of the present invention, the upper chemical liquid supply unit is configured to be swingable to move from a central portion to an edge portion of the substrate while spraying a chemical liquid, and a rotational speed of the substrate at a second position between the second bowl and the third bowl may be configured to be faster than a rotational speed of the substrate at a lowermost position.

In one embodiment of the present invention, in step (a), the substrate may be loaded onto the substrate rotation module in a state in which a separation distance between a lower surface of the substrate and an upper surface of the spin chuck provided in the substrate rotation module is 0.5 to 20 mm.

### Advantageous Effects

Effects of the substrate cleaning apparatus and the substrate cleaning method using the same according to the present invention described above are as follows.

According to the present invention, cleaning of the substrate is performed while the lower surface of the substrate is immersed in the chemical liquid filled in the chemical-liquid filling space. Accordingly, it is possible to prevent the problem in which cleaning of the lower surface of the substrate is not properly performed in the conventional art. Therefore, the substrate cleaning operation can be effectively performed.

According to the present invention, since the plurality of lamps provided below the spin chuck transmit thermal energy generated from the lamps to the substrate through the chemical liquid received in the chemical-liquid filling space, linear heat transfer to the substrate can be achieved. In addition, since the plurality of lamps disposed at predetermined intervals are individually controllable, it is possible to selectively adjust an amount of heat generation of the lamps depending on positions on the substrate where the lamps are disposed. Accordingly, a uniform temperature can be maintained across the substrate. Further, since the lamps are provided below the spin chuck, interference with the swingable upper chemical liquid supply unit does not occur, and the structure of the substrate cleaning apparatus can be simplified.

The effects of the present invention are not limited to the above-described effects, and it should be understood to include all effects that can be derived from configurations of the invention described in the detailed description of the invention or the claims.

### BRIEF DESCRIPTION OF THE DRAWINGS

FIG. 1 is a configuration diagram of a substrate cleaning apparatus according to one embodiment of the present invention.

FIG. 2 is a perspective view of the substrate cleaning apparatus according to one embodiment of the present invention, viewed from above.

FIG. 3 is a perspective view of the substrate cleaning apparatus according to one embodiment of the present invention, viewed from below.

FIG. 4 is a cross-sectional view taken along line A-A′ of FIG. 2.

FIG. 5 is a partial cross-sectional view of a substrate rotation module according to one embodiment of the present invention.

FIG. 6 is an exemplary view showing a state in which a chemical liquid discharge blade is inserted into a blade insertion groove according to one embodiment of the present invention.

FIG. 7 is a flowchart illustrating a substrate cleaning method according to one embodiment of the present invention.

FIG. 8 is an exemplary view schematically showing a state in which a substrate rotation module or a bowl module is moved during a substrate cleaning process according to one embodiment of the present invention.

### MODE FOR CARRYING OUT THE INVENTION

Hereinafter, embodiments of the present invention will be described with reference to the accompanying drawings. However, the present invention may be implemented in various different forms, and thus is not limited to the embodiments described herein. In order to clearly describe the present invention in the drawings, parts irrelevant to the description are omitted, and similar reference numerals are assigned to similar parts throughout the specification.

Throughout the specification, when a certain part is described as being “connected” to another part, this includes not only a case of being “directly connected” but also a case of being “indirectly connected” with another member interposed therebetween. In addition, when a certain part “includes” a certain component, this means that other components may be further included unless otherwise stated, rather than excluding other components. In the present invention, “upper” and “lower” mean being located above or below a target member, and do not necessarily mean being located above or below with respect to a direction of gravity.

Hereinafter, an embodiment of the present invention will be described in detail with reference to the accompanying drawings.

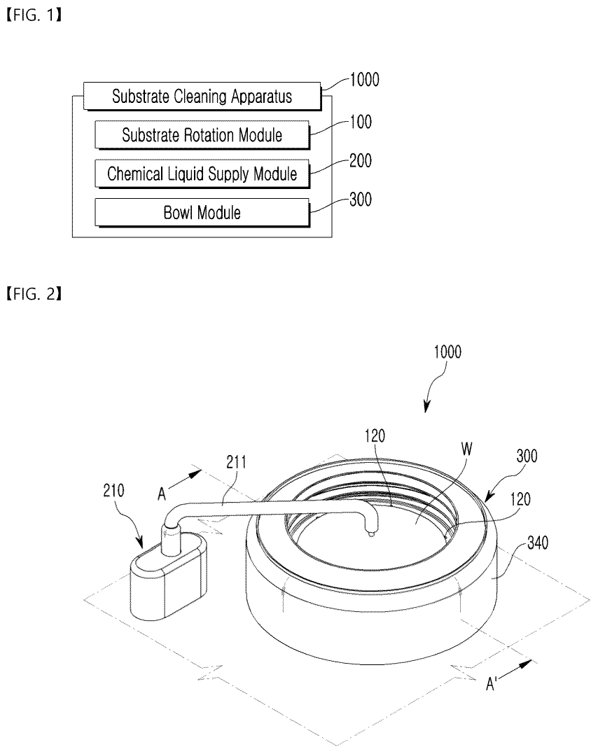

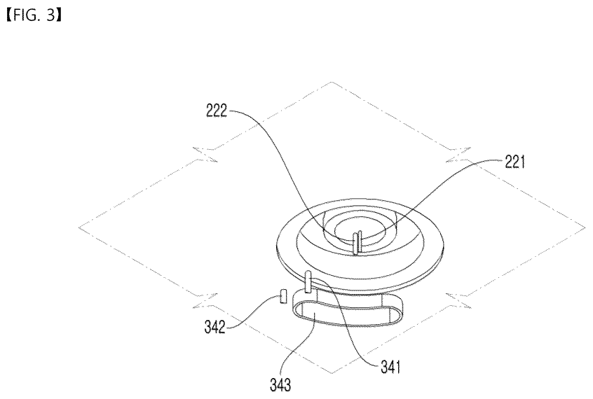

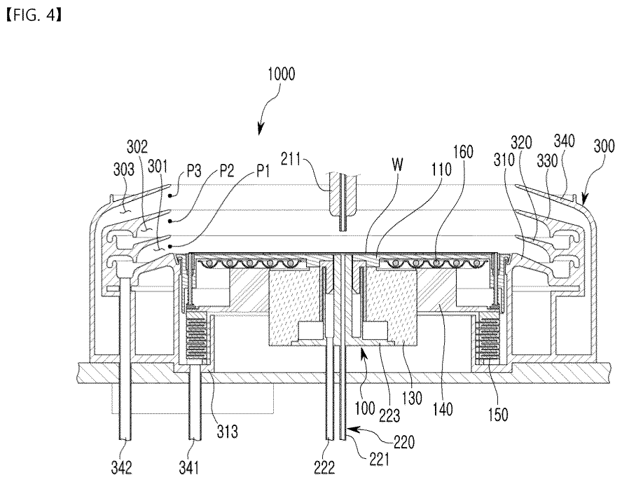

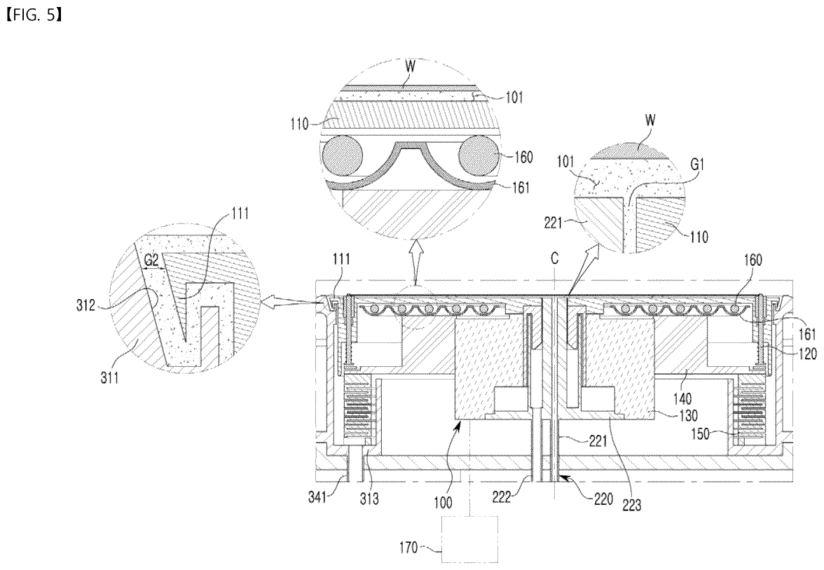

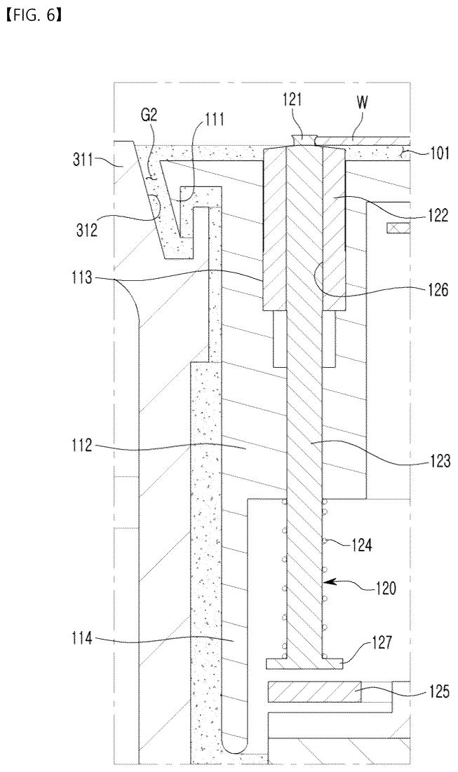

FIG. 1 is a configuration diagram of a substrate cleaning apparatus according to one embodiment of the present invention, FIG. 2 is a perspective view of the substrate cleaning apparatus according to one embodiment of the present invention viewed from above, FIG. 3 is a perspective view of the substrate cleaning apparatus according to one embodiment of the present invention viewed from below, FIG. 4 is a cross-sectional view taken along line A-A′ of FIG. 2, FIG. 5 is a partial cross-sectional view of a substrate rotation module according to one embodiment of the present invention, and FIG. 6 is an exemplary view showing a state in which a chemical liquid discharge blade is inserted into a blade insertion groove according to one embodiment of the present invention.

As shown in FIGS. 1 to 6, a substrate cleaning apparatus (1000) may include a substrate rotation module (100), a chemical liquid supply module (200), and a bowl module (300).

The substrate rotation module (100) supports and fixes a loaded substrate (W), and controls rotation of the substrate (W) and upward and downward movement of the substrate (W). Here, the substrate (W) may be a silicon wafer, which is a semiconductor substrate.

The substrate rotation module (100) may include a spin chuck (110), substrate fixing units (120), a rotational driving unit (130), a power support unit (140), and a bellows (150).

Here, the spin chuck (110) is coupled to the rotational driving unit (130). The spin chuck (110) receives rotational force provided from the rotational driving unit (130) and rotates the substrate (W).

The substrate fixing units (120) are provided at an edge of the spin chuck (110), and may be provided in plurality at predetermined intervals along a circumference of the spin chuck (110).

The substrate fixing units (120) are configured to support and fix a periphery of the loaded substrate (W). In the present invention, a form in which six substrate fixing units (120) are provided is illustrated as an example, but the number of substrate fixing units (120) is not limited to six, and may be various numbers other than six.

The substrate fixing units (120) are configured to support and fix the substrate (W) loaded onto the substrate rotation module (100) in a state in which the substrate (W) is spaced apart from an upper surface of the spin chuck (110) by a predetermined distance.

Each substrate fixing unit (120) may include a chuck pin (121), a chuck pin pressing part (122), a chuck pin shaft (123), a spring (124), and a height adjustment ring (125).

Here, the chuck pin (121) is configured to support an upper edge portion of the substrate (W). The chuck pin (121) may be moved upward and downward by operation of the height adjustment ring (125).

The chuck pin pressing part (122) is configured to support a lower edge portion of the loaded substrate (W) together with the chuck pin (121). The chuck pin pressing part (122) is inserted and fixed into a chuck fixing groove (113) formed in a chuck pin support portion (112).

The chuck pin shaft (123) is inserted through a shaft through hole (126) formed in the chuck pin pressing part (122). An upper end of the chuck pin shaft (123) is coupled to the chuck pin (121), and the chuck pin shaft (123) and the chuck pin (121) form an integral body.

The spring (124) is inserted through the chuck pin shaft (123), and one end thereof is supported by the chuck pin support portion (112) and the other end thereof is supported by a pressing support surface (127). Here, the pressing support surface (127) is coupled to a lower end of the chuck pin shaft (123) and supports the spring (124).

The height adjustment ring (125) presses the pressing support surface (127) and guides upward and downward movement of the chuck pin shaft (123). An upward/downward movement adjustment unit (not shown) for adjusting upward/downward movement of the height adjustment ring (125) is coupled to the height adjustment ring (125), and thus the height adjustment ring (125) can move upward and downward to a required height.

A process of loading the substrate (W) onto the substrate rotation module (100) will be briefly described. First, the height adjustment ring (125) is moved upward. In this process, the spring (124) is compressed, and the chuck pin shaft (123) moves upward. The chuck pin (121) coupled to the chuck pin shaft (123) also moves upward together with the chuck pin shaft (123).

As the chuck pin (121) moves upward with respect to the chuck pin pressing part (122), a substrate insertion space is provided between the chuck pin (121) and the chuck pin pressing part (122), and a robot transfers the substrate (W) into the substrate insertion space. Next, the height adjustment ring (125) moves downward. In this process, the chuck pin (121) moves downward to support the upper edge portion of the substrate (W), and the chuck pin pressing part (122) supports the lower edge portion of the substrate (W). At this time, the chuck pin (121) stably supports and fixes the substrate (W) by restoration force of the spring (124).

Here, the substrate (W) supported and fixed by the substrate fixing units (120) is fixed in a state in which the substrate (W) is spaced apart from the upper surface of the spin chuck (110) by a predetermined distance. At this time, a separation distance between a lower surface of the substrate (W) and the upper surface of the spin chuck (110) may be 0.5 to 20 mm. When the separation distance is less than 0.5 mm, the substrate (W) may be damaged in the loading process. When the separation distance exceeds 20 mm, a chemical liquid cleaning operation for the lower surface of the substrate (W) may not be effectively performed. Accordingly, it is preferable that the separation distance is 0.5 to 20 mm. More preferably, the separation distance is 1 to 3 mm.

In a state in which the substrate (W) is loaded onto the substrate rotation module (100) as described above, the substrate rotation module (100) moves downward. Here, the substrate rotation module (100) is provided with a movement control unit (170) for moving the substrate rotation module (100) upward and downward, and thus the substrate rotation module (100) can move upward and downward to a required position.

The substrate (W) moved downward by the movement control unit (170) is cleaned while the lower surface of the substrate (W) is immersed in a chemical liquid filled in a chemical-liquid filling space (101). Here, a chemical liquid receiving ledge (311) is formed in a first bowl (310) so that a chemical liquid can be filled in the chemical-liquid filling space (101). Accordingly, for an initial cleaning operation, the lower surface of the substrate (W) moved to a first position (P1) can be immersed in a chemical liquid received in the chemical-liquid filling space (101). The chemical-liquid filling space (101) may be filled with a first chemical liquid supplied from a lower chemical liquid supply unit (220).

Specifically, in a state in which a chemical liquid discharge blade (111) provided at a periphery of the spin chuck (110) is inserted into a blade insertion groove (312) of the first bowl (310), the chemical liquid receiving ledge (311) provides a receiving space capable of receiving the first chemical liquid together with the upper surface of the spin chuck (110). That is, the upper surface of the spin chuck (110) forms a bottom surface of the chemical-liquid filling space (101), and the chemical liquid receiving ledge (311) forms a side surface of the chemical-liquid filling space (101), and thus the first chemical liquid can be filled in the chemical-liquid filling space (101). Accordingly, the lower surface of the substrate (W) can be immersed in the first chemical liquid received in the chemical-liquid filling space (101).

In a state in which the chemical liquid discharge blade (111) is inserted into the blade insertion groove (312), an upper end of the chemical liquid receiving ledge (311) is disposed higher than the lower surface of the substrate (W) and lower than the upper surface of the substrate (W). Accordingly, the lower surface of the substrate (W) can be immersed in the first chemical liquid received in the chemical-liquid filling space (101). Further, not only the lower surface of the substrate (W) but also a portion of a side surface of the substrate (W) can be immersed in the first chemical liquid.

Here, in a process in which a lower chemical liquid nozzle (221) provided in the lower chemical liquid supply unit (220) sprays the first chemical liquid toward the lower surface of the substrate (W), a portion of the first chemical liquid received in the chemical-liquid filling space (101) is discharged. For example, an upper end portion of the lower chemical liquid nozzle (221) is inserted through a center of the spin chuck (110). Here, since the lower chemical liquid nozzle (221) is fixed and the spin chuck (110) rotates, a fine first separation space (G1) is formed between the lower chemical liquid nozzle (221) and the spin chuck (110), and the first chemical liquid introduced into the first separation space (G1) can be discharged through a central drain port (222). In addition, the first chemical liquid introduced into a second separation space (G2) between the chemical liquid discharge blade (111) and the blade insertion groove (312) can be discharged through a bottom drain port (341).

Meanwhile, the blade insertion groove (312) has a groove shape inclined such that the blade insertion groove (312) becomes closer to a central axis line (C) from an upper side to a lower side. In discharge of the first chemical liquid filled in the chemical-liquid filling space (101) through the second separation space (G2), such an inclined blade insertion groove (312) is configured to delay smooth discharge of the first chemical liquid. Through this, the first chemical liquid can be effectively filled in the chemical-liquid filling space (101).

An extension guide (114) is coupled to the chuck pin support portion (112) provided on a lower outer circumference of the spin chuck (110). The extension guide (114) is configured to extend from the chuck pin support portion (112).

The extension guide (114) is configured to prevent the first chemical liquid introduced into the second separation space (G2) and discharged to the bottom drain port (341) from flowing into components such as the rotational driving unit (130) provided on an inner side of the extension guide (114). That is, the extension guide (114), together with the bellows (150), prevents the first chemical liquid introduced into the second separation space (G2) from penetrating into various components provided on the inner side of the extension guide (114), such as the rotational driving unit (130), the height adjustment ring (125), and the spring (124). Accordingly, corrosion of the rotational driving unit (130) and the various components due to the first chemical liquid can be prevented.

The extension guide (114) is disposed outside the bellows (150). At this time, a lower end of the extension guide (114) is disposed lower than an upper end of the bellows (150), thereby preventing the first chemical liquid from penetrating between the extension guide (114) and the bellows (150).

A hollow portion into which the rotational driving unit (130) is inserted and fixed is formed at a center of the power support unit (140), and the rotational driving unit (130) inserted into the hollow portion can be supported by the power support unit (140). Here, the rotational driving unit (130) rotating the spin chuck (110) may be, for example, a motor.

One end of the bellows (150) is coupled to the power support unit (140), and the other end of the bellows (150) is coupled to a seating surface (313) formed in the first bowl (310). The bellows (150) expands and contracts in a process in which the movement control unit (170) moves the rotational driving unit (130) upward and downward, and prevents the chemical liquid from penetrating into an inner side of the bellows (150).

Meanwhile, the substrate rotation module (100) may further include lamps (160).

The lamps (160) may be provided on a lower surface of the spin chuck (110). For example, the lamps (160) may be provided in plurality at predetermined intervals in an outward direction with respect to the central axis line (C).

The lamps (160) transmit thermal energy generated from the lamps (160) to the substrate (W) through the first chemical liquid received in the chemical-liquid filling space (101), and thus the substrate (W) can maintain a required predetermined temperature. Here, a reflector (161) is provided below the lamps (160) so that thermal energy generated from the lamps (160) can be effectively transmitted toward the lower surface of the substrate (W).

The plurality of lamps (160) can selectively adjust an amount of heat generation of the lamps (160) depending on positions on the substrate (W) where the lamps (160) are disposed. That is, the plurality of lamps (160) may be configured to be individually controllable. For example, a central portion of the substrate (W) in which a high-temperature first chemical liquid of 120 °C or higher is discharged through the lower chemical liquid nozzle (221) may become close to the temperature of the first chemical liquid, but as it goes toward the edge portion of the substrate (W), the temperature of the substrate (W) may decrease. Accordingly, the lamps (160) disposed at an outer side of the substrate (W) may be controlled such that an amount of heat generation is higher than that of the lamps (160) disposed at the central portion. As such, the plurality of lamps (160) can be individually controlled for each position so that the substrate (W) maintains a uniform temperature overall. The lamps (160) may be, for example, infrared lamps, and any lamps may be used as long as the temperature of the substrate (W) can be effectively increased.

Meanwhile, the chemical liquid supply module (200) may include an upper chemical liquid supply unit (210) and a lower chemical liquid supply unit (220).

An upper chemical liquid nozzle (211) provided in the upper chemical liquid supply unit (210) is configured to spray a chemical liquid toward the upper surface of the substrate (W). The upper chemical liquid nozzle (211) is configured to be swingable, and thus can move from a central portion to an edge portion of the substrate (W) while spraying a chemical liquid.

The upper chemical liquid nozzle (211) may selectively adjust a speed of movement from the central portion to the edge portion while spraying a chemical liquid toward the upper surface of the substrate (W). Alternatively, the upper chemical liquid nozzle (211) may repeatedly move from the central portion to the edge portion while spraying a chemical liquid, and may remain for a longer time at a substrate portion requiring more cleaning while spraying a chemical liquid. As such, the upper chemical liquid nozzle (211) performs a cleaning operation on the upper surface of the substrate (W) through various methods.

The upper chemical liquid nozzle (211) may be provided in plurality. For example, separate nozzles may be provided, such as a nozzle spraying the first chemical liquid, a nozzle spraying a second chemical liquid, a nozzle performing a rinsing operation, and a nozzle performing a drying operation. In the present invention, a form in which one upper chemical liquid nozzle (211) performs spraying of the first chemical liquid and the second chemical liquid and performs rinsing and drying operations will be described.

The lower chemical liquid supply unit (220) is configured to spray a chemical liquid toward the lower surface of the substrate (W).

The lower chemical liquid supply unit (220) may include the lower chemical liquid nozzle (221) and the central drain port (222).

Here, unlike the upper chemical liquid nozzle (211), the lower chemical liquid nozzle (221) is fixed. A flange (223) is provided in the lower chemical liquid nozzle (221), and the flange (223) is coupled to a lower portion of the rotational driving unit (130). The lower chemical liquid nozzle (221) is configured to perform spraying of the first chemical liquid and the second chemical liquid and to perform rinsing and drying operations, like the upper chemical liquid nozzle (211) described above.

The central drain port (222) is configured to discharge to the outside the chemical liquid introduced into the first separation space (G1) between the spin chuck (110) and the lower chemical liquid nozzle (221).

Meanwhile, the bowl module (300) is disposed outside the substrate rotation module (100) and is configured to discharge the chemical liquid scattered from the substrate (W) by rotation.

The bowl module (300) may include the first bowl (310), a second bowl (320), a third bowl (330), and a bowl casing (340).

A chemical liquid receiving ledge (311) is provided in the first bowl (310) so that a chemical liquid can be filled in the chemical-liquid filling space (101).

The second bowl (320) is spaced apart above the first bowl (310). The second bowl (320) forms a first discharge space (301) together with the first bowl (310). The chemical liquid discharged through the first discharge space (301) can be discharged through a side drain port (342) penetrating the first bowl (310).

The third bowl (330) is spaced apart above the second bowl (320). The third bowl (330) forms a second discharge space (302) together with the second bowl (320). The chemical liquid discharged through the second discharge space (302) can be discharged through a chemical liquid drain unit (not shown).

The bowl casing (340) is spaced apart above the third bowl (330), forms a third discharge space (303) together with the third bowl (330), and rinse liquid for rinsing of the substrate (W) and gas for drying of the substrate (W) discharged through the third discharge space (303) can be discharged to an external discharge port (343).

The bowl casing (340) protects the first bowl (310) to the third bowl (330) from the outside. The bowl module (300) prevents the chemical liquid scattered from the substrate (W) from being scattered outside the bowl module (300).

In one embodiment of the present invention, the bowl module (300) is described as including the first bowl (310), the second bowl (320), the third bowl (330), and the bowl casing (340) as an example; however, the number of bowls provided in the bowl module (300) is not limited to the first bowl (310) to the third bowl (330), and for example, a fourth bowl (not shown), a fifth bowl (not shown), etc. may be further provided. That is, the number of bowls provided in the bowl module (300) may be various.

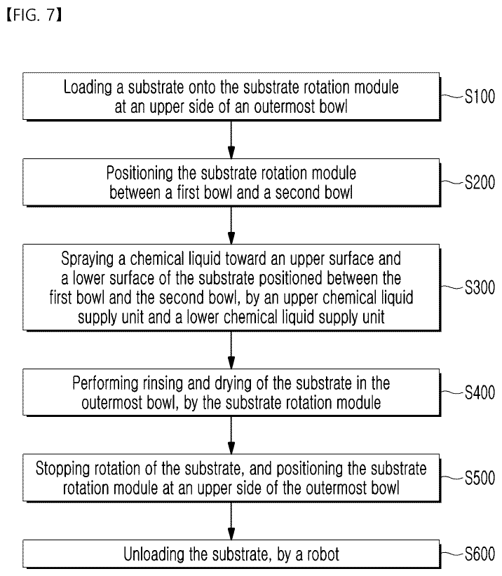

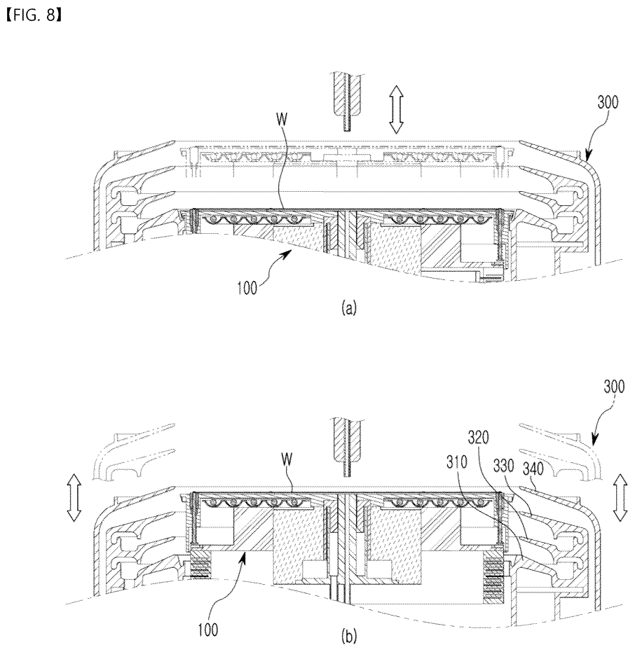

FIG. 7 is a flowchart illustrating a substrate cleaning method according to one embodiment of the present invention, and FIG. 8 is an exemplary view schematically showing a state in which a substrate rotation module or a bowl module is moved during a substrate cleaning process according to one embodiment of the present invention.

In description of the substrate cleaning method according to the present invention, a form in which the bowl module (300) includes the first bowl (310), the second bowl (320), the third bowl (330), and the bowl casing (340) will be described as an example. Here, the third bowl (330) may be an outermost bowl among the plurality of bowls, i.e., the first bowl (310) to the third bowl (330).

As shown in FIG. 8, in adjustment of a relative position between the substrate rotation module (100) and the bowl module (300) in a process of cleaning the substrate (W) loaded onto the substrate rotation module (100), as shown in FIG. 8 (a), the substrate rotation module (100) may move upward and downward while the bowl module (300) is fixed, or as shown in FIG. 8 (b), the bowl module (300) may move upward and downward while the substrate rotation module (100) is fixed. Here, when the bowl module (300) moves upward and downward, the bowl module (300) as a whole may move upward and downward, or when the first bowl (310) to the third bowl (330) are individually separated, the first bowl (310) to the third bowl (330) may individually move upward and downward.

In description of the substrate cleaning method according to the present invention, a form in which the substrate rotation module (100) moves upward and downward while the bowl module (300) is fixed will be described as an example.

A process of operation of the substrate cleaning apparatus (1000) will be briefly described with reference to FIG. 7. First, the substrate (W) is loaded onto the substrate rotation module (100). That is, the substrate (W) is loaded onto the substrate rotation module (100) at an upper side of an outermost bowl, i.e., the third bowl (330). At this time, the substrate (W) transferred by a robot can be supported and fixed by the substrate fixing units (120). Here, the substrate (W) can be loaded onto the substrate rotation module (100) in a state in which a separation distance between the lower surface of the substrate (W) and the upper surface of the spin chuck (110) provided in the substrate rotation module (100) is 0.5 to 20 mm. (S100)

Next, the substrate rotation module (100) rotates the substrate (W) and moves downward. Here, the substrate rotation module (100) moves to a first position (P1) between the first bowl (310), which is the lowermost bowl, and the second bowl (320). At this time, the position of the substrate rotation module (100) may be a position in which the lower surface of the substrate (W) can be immersed by the first chemical liquid received in the chemical-liquid filling space (101). (S200)

Next, the upper chemical liquid supply unit (210) sprays the first chemical liquid toward the upper surface of the substrate (W), and the lower chemical liquid supply unit (220) sprays the first chemical liquid toward the lower surface of the substrate (W). In this process, the substrate (W) rotates in a state in which the lower surface of the substrate (W) is immersed by the first chemical liquid filled in the chemical-liquid filling space (101). Here, the first chemical liquid sprayed toward the substrate (W) through the upper chemical liquid supply unit (210) and the lower chemical liquid supply unit (220) may be, for example, an aqueous phosphoric acid solution. The first chemical liquid is not limited only to an aqueous phosphoric acid solution, and may be another chemical liquid. (S300)

The first chemical liquid scattered from the substrate (W) rotating at the first position (P1) is discharged through the first discharge space (301) formed between the first bowl (310) and the second bowl (320). In this process, the plurality of lamps (160), which are coupled to the lower surface of the spin chuck (110) and disposed at predetermined intervals in an outward direction with respect to the central axis line (C), may be operated to maintain the substrate (W) at a predetermined temperature. The lamps (160) are configured to transmit thermal energy generated from the lamps (160) to the substrate (W) through the first chemical liquid received in the chemical-liquid filling space (101). As such, since the first chemical liquid received in the chemical-liquid filling space (101) absorbs thermal energy generated from the lamps (160) and then transmits heat to the substrate (W), linear heat transfer to the substrate (W) can be achieved.

The upper chemical liquid supply unit (210) spraying the first chemical liquid toward the upper surface of the substrate (W) is configured to be swingable, and can, for example, move from the central portion to the edge portion of the substrate (W) while spraying the first chemical liquid toward the upper surface of the substrate (W).

In a process in which the upper chemical liquid supply unit (210) sprays the first chemical liquid toward the upper surface of the substrate (W) and the lower chemical liquid supply unit (220) simultaneously sprays the first chemical liquid toward the lower surface of the substrate (W), the first chemical liquid scattered from the rotating substrate (W) is discharged to the first discharge space (301), and at the same time, a portion of the first chemical liquid filled in the chemical-liquid filling space (101) is discharged to the central drain port (222) and the bottom drain port (341).

Next, the substrate rotation module (100) moves the substrate (W) to a second position (P2) between the second bowl (320) and the third bowl (330). In a process of moving the substrate (W) from the first position (P1) to the second position (P2), the substrate rotation module (100) increases the rotational speed of the substrate (W).

Next, in a state in which the substrate (W) is moved to the second position (P2), the upper chemical liquid supply unit (210) sprays the second chemical liquid toward the upper surface of the substrate (W), and the lower chemical liquid supply unit (220) sprays the second chemical liquid toward the lower surface of the substrate (W). Here, the second chemical liquid sprayed toward the substrate (W) may be a chemical liquid for cleaning the substrate (W) that is different from the first chemical liquid.

Since the rotational speed of the substrate (W) at the second position (P2) is faster than the rotational speed of the substrate (W) at the first position (P1), the second chemical liquid sprayed toward the substrate (W) moves from the central portion to the edge portion of the substrate (W) and can then be entirely discharged through the second discharge space (302) formed between the second bowl (320) and the third bowl (330).

Next, the substrate rotation module (100) performs rinsing and drying operations on the substrate (W) in a state in which the substrate (W) is moved to a third position (P3), which is the uppermost position between the third bowl (330) and the bowl casing (340). (S400)

That is, the upper chemical liquid supply unit (210) and the lower chemical liquid supply unit (220) perform rinsing and drying operations on the substrate (W) moved to the third position (P3), which is the uppermost position. Here, the rinse liquid may be, for example, deionized water (DI water) in which ionic components are removed from water. The substrate (W) that has completed the rinsing operation may be dried by rotating at a speed faster than the rotational speed of the substrate (W) at the second position (P2). Alternatively, the upper chemical liquid supply unit (210) and the lower chemical liquid supply unit (220) may dry the substrate (W) by discharging, for example, nitrogen gas toward the substrate (W). Water or gas discharged through the third discharge space (303) during the rinsing and drying process of the substrate (W) can be discharged to the external discharge port (343).

Next, the substrate rotation module (100) moves the substrate (W) to an upper side of the third position (P3) at which loading of the substrate (W) was performed, in a state in which rotation of the substrate (W) is stopped. That is, the substrate rotation module (100) positions the cleaned substrate (W) above the third bowl (330), which is the outermost bowl. (S500)

Finally, the substrate (W) supported and fixed by the substrate rotation module (100) is released from fixing by the substrate fixing units (120), and the robot unloads the substrate (W) from the substrate rotation module (100). (S600)

However, the above is only a preferred embodiment of the present invention, and the scope of rights of the present invention is not limited by the described embodiment.

The above description of the present invention is for illustration, and those skilled in the art to which the present invention pertains will understand that various modifications can be easily made without changing the technical spirit or essential features of the present invention. Therefore, the embodiments described above should be understood to be illustrative in all aspects and not restrictive. For example, components described in a singular form may be implemented in a distributed form, and likewise, components described as being distributed may be implemented in a combined form.

The scope of the present invention is indicated by the claims described below, and all changes or modified forms derived from the meaning and scope of the claims and the concept of equivalents thereof should be construed as being included in the scope of the present invention.

What is claimed is:

1. A substrate cleaning apparatus comprising:
a substrate rotation module configured to support and fix a substrate for cleaning and to rotate the substrate about a virtual central axis line;
a chemical liquid supply module having an upper chemical liquid supply unit configured to supply a chemical liquid to an upper surface of the substrate and a lower chemical liquid supply unit configured to supply a chemical liquid to a lower surface of the substrate; and
a bowl module disposed outside the substrate rotation module and configured to discharge the chemical liquid scattered from the substrate by rotation,
wherein a chemical-liquid filling space is formed between an upper surface of a spin chuck provided in the substrate rotation module and a lower surface of the substrate fixed to the substrate rotation module, and
wherein cleaning of the substrate is performed while the lower surface of the substrate is immersed in the chemical liquid filled in the chemical-liquid filling space.

2. The substrate cleaning apparatus of claim 1,
wherein a chemical liquid discharge blade provided at a periphery of the spin chuck is inserted into a blade insertion groove of a first bowl provided in the bowl module, and
wherein, in a state in which the chemical liquid discharge blade is inserted into the blade insertion groove, an upper end of a chemical liquid receiving ledge forming the blade insertion groove is disposed higher than the lower surface of the substrate and lower than the upper surface of the substrate.

3. The substrate cleaning apparatus of claim 2,
wherein the blade insertion groove forms a second separation space with the chemical liquid discharge blade, and
wherein the blade insertion groove is formed to be inclined such that the blade insertion groove becomes closer to the central axis line from an upper side to a lower side.

4. The substrate cleaning apparatus of claim 1,
wherein a plurality of lamps are provided on a lower surface of the spin chuck at predetermined intervals in an outward direction with respect to the central axis line, and
wherein thermal energy generated from the plurality of lamps is transmitted to the substrate through the chemical liquid received in the chemical-liquid filling space such that the substrate maintains a predetermined temperature, and
wherein the plurality of lamps are configured to be individually controllable.

5. The substrate cleaning apparatus of claim 1,
wherein the substrate rotation module comprises:
a spin chuck;
a plurality of substrate fixing units disposed at predetermined intervals along an outer circumference of the spin chuck and configured to support and fix a periphery of the substrate in a state in which the substrate is spaced apart from an upper surface of the spin chuck by a predetermined distance;
a rotational driving unit configured to rotate the spin chuck;
a power support unit having a hollow portion into which the rotational driving unit is inserted and fixed and configured to support the rotational driving unit; and
a bellows having one end coupled to the power support unit and the other end coupled to a seating surface formed in the bowl module.

6. The substrate cleaning apparatus of claim 5,
wherein each of the plurality of substrate fixing units comprises:
a chuck pin configured to support an upper edge portion of the substrate;
a chuck pin pressing part inserted into a chuck fixing groove formed in the spin chuck and configured to support a lower edge portion of the substrate together with the chuck pin;
a chuck pin shaft inserted through the chuck pin pressing part, the chuck pin shaft having an upper end coupled to the chuck pin;
a spring inserted through the chuck pin shaft, with one end supported by a chuck pin support portion in which the chuck fixing groove is formed and the other end supported by a pressing support surface provided at a lower end portion of the chuck pin shaft; and
a height adjustment ring configured to press the pressing support surface and to guide upward and downward movement of the chuck pin shaft.

7. The substrate cleaning apparatus of claim 6,
wherein an extension guide coupled to the chuck pin support portion is disposed outside the bellows, and
wherein a lower end of the extension guide is disposed lower than an upper end of the bellows.

8. The substrate cleaning apparatus of claim 1,
wherein the lower chemical liquid supply unit comprises:
a lower chemical liquid nozzle configured to spray a chemical liquid toward the lower surface of the substrate; and
a central drain port configured to discharge the chemical liquid introduced into a first separation space between the lower chemical liquid nozzle and the spin chuck to the outside.

9. The substrate cleaning apparatus of claim 1,
wherein the bowl module comprises:
a first bowl;
a second bowl spaced apart above the first bowl and forming a first discharge space together with the first bowl;
a third bowl spaced apart above the second bowl and forming a second discharge space together with the second bowl; and
a bowl casing spaced apart above the third bowl, forming a third discharge space together with the third bowl, and protecting the first to the third bowls.

10. The substrate cleaning apparatus of claim 9,
wherein a seating surface to which a lower portion of a bellows provided in the substrate rotation module is coupled is formed in the first bowl,
wherein a bottom drain port for discharging the chemical liquid introduced through a second separation space between a chemical liquid discharge blade provided at a periphery of a spin chuck and a blade insertion groove is provided in the seating surface, and
wherein the chemical liquid discharged through the first discharge space is discharged through a side drain port penetrating the first bowl.

11. A substrate cleaning method comprising:
(a) loading a substrate onto a substrate rotation module at an upper side of an outermost bowl;
(b) positioning the substrate rotation module between a first bowl and a second bowl;
(c) spraying a chemical liquid toward an upper surface and a lower surface of the substrate positioned between the first bowl and the second bowl, by an upper chemical liquid supply unit and a lower chemical liquid supply unit;
(d) performing rinsing and drying of the substrate in the outermost bowl, by the substrate rotation module;
(e) stopping rotation of the substrate, and positioning the substrate rotation module at an upper side of the outermost bowl; and
(f) unloading the substrate, by a robot,
wherein, in step (b), the substrate is cleaned while the lower surface of the substrate is immersed in a chemical liquid received in a chemical-liquid filling space.

12. The substrate cleaning method of claim 11,
wherein, in step (c), a plurality of lamps are provided on a lower surface of a spin chuck provided in the substrate rotation module at predetermined intervals in an outward direction with respect to a central axis line, and
wherein the plurality of lamps transmit thermal energy to the substrate through the chemical liquid received in the chemical-liquid filling space to maintain the substrate at a predetermined temperature.

13. The substrate cleaning method of claim 11,
wherein the upper chemical liquid supply unit is configured to be swingable to move from a central portion to an edge portion of the substrate while spraying a chemical liquid, and
wherein a rotational speed of the substrate at a second position between a second bowl and a third bowl is configured to be faster than a rotational speed of the substrate at a lowermost position.

14. The substrate cleaning method of claim 11,
wherein, in step (a), the substrate is loaded onto the substrate rotation module in a state in which a separation distance between the lower surface of the substrate and an upper surface of a spin chuck provided in the substrate rotation module is 0.5 to 20 mm.
